(19) United States
(12) Patent Application Publication
(10) Pub. No.: US 2026/0364657 A1
(43) Pub. Date: Nov. 19, 2026

(54) MECHANICALLY, IN PARTICULAR TRIBOLOGICALLY, STRESSED COMPONENT AND METHOD FOR ITS PRODUCTION

(71) Applicant: SMS group GmbH, Mönchengladbach (DE)

(72) Inventors: Joachim OHLERT, Cologne (DE); Matthias KIPPING, Herdorf (DE)

(73) Assignee: SMS group GmbH, Mönchengladbach (DE)

(21) Appl. No.: 19/136,525

(22) PCT Filed: Dec. 6, 2023
(86) PCT No.: PCT/EP2023/084622

§ 371 Date: Jun. 6, 2025

(30) Foreign Application Priority Data
Dec. 7, 2022 (DE) 10 2022 213 177.0

(51) Int. Cl. B21B 27/02; B21B 1/22; B23P 6/00

(52) U.S. Cl. CPC B21B 27/02; B21B 1/22; B23P 6/00; B21B 2001/225

(57) ABSTRACT

A mechanically, in particular tribologically, stressed component in a rolling mill, includes a main body of a base material and at least one functional layer (3) applied to the main body and at least one material different from the base material. The material of the at least one functional layer (3) has a greater wear resistance than the base material. The main body includes at least one further, outer layer as a sacrificial layer (5), which at least partially encloses the at least one functional layer (3). The sacrificial layer (5) consists of a material which has a lower wear resistance than the at least one functional layer (3).

### CROSS-REFERENCE TO RELATED APPLICATION

This application is a national stage application, filed under 35 U.S.C. §371, of International Patent Application PCT/EP2023/084622, filed on Dec. 6, 2023, which claims the benefit of German Patent Application DE 10 2022 213 177.0, filed on Dec. 7, 2022.

### TECHNICAL FIELD

The invention relates to a mechanically, in particular tribologically, stressed component in a rolling mill and a method for producing or restoring such a component. A mechanically, in particular tribologically, stressed component may, for example, be a sliding guide, a linear guide, a guide ruler or a roll or cylinder which, for example, is in contact with the rolled material and is configured as a wear partner in terms of its material configuration.

The invention relates in particular to a roll for use on rolled material in a rolling mill and a method for producing or restoring a roll for use on rolled material in a rolling mill, in particular in a hot rolling mill.

### BACKGROUND

A mechanically stressed roll is known, for example, from WO 2009/130079A1. This publication relates to a roll for transporting continuously cast steel strands on a roller table or in a continuous casting machine, with a roller body comprising a roll shell of a base material and a wear layer applied by build-up welding to the base material with a welding filler material and enclosing the roll shell surface, wherein the base material of the roll shell is steel. The application instructions are carried out using single-layer welding. The roll is restored after wear by the roll shell being provided as a turned part and a single-layer build-up weld being applied to the base material with a certain minimum thickness. The welded layer is then rolled back onto a closed single-surface roll shell surface while maintaining a minimum thickness of the wear layer.

Mechanical components are often exposed to loads during operation that vary locally and do not affect the component evenly. In particular, a difference between the core and the edge of a component is often observed. In predominantly cylindrical components, such as discs and shafts or rolls as well as other components with flat surfaces, the core is often required to have high ductility at low load, while the boundary area near the surface is, for example, exposed to high mechanical, thermal and/or corrosive stress.

For this reason, it is well known to provide rolls, such as those described in WO 2009/130079A1, for example, with coatings that perform different functions, for example increased wear resistance, increased bending or torsion resistance under static, dynamic or oscillating load, increased temperature resistance, a certain thermal expansion or thermal conductivity and increased corrosion resistance.

As described above, it is known to apply such functional layers by build-up welding, thermal spraying, vapour deposition, dusting, galvanic or chemical coating or casting. Often, a specific surface quality is required for such components, that is to say, for example, a defined roughness and waviness. This surface quality is not necessarily present after applying the functional layers; rather, it must be achieved through appropriate reworking, such as turning, milling or grinding.

In components that are to be given increased wear resistance by applying what is referred to as a functional layer, the production of certain surface properties through reworking is naturally relatively complex, since a more wear-resistant material resists reworking more than a material that is less wear-resistant.

### SUMMARY

An object underlying the invention is to provide a component for use in particular on hot rolled material in a rolling mill, which component is optimized with regard to its wear properties and which can be produced and/or restored relatively easily.

A further object underlying the invention is to provide a corresponding method for producing and/or restoring such a component.

The object is solved by the features as claimed.

According to one aspect, a mechanically, in particular tribologically, stressed component with a main body of a base material and at least one functional layer applied to the main body is provided, wherein the material of the at least one functional layer has a greater wear resistance than the base material, wherein the main body comprises at least one further, outer layer as a sacrificial layer, which at least partially encloses the at least one functional layer, and the sacrificial layer consists of a material which has a lower wear resistance than the at least one functional layer.

As used in this application, a mechanically stressed component is, for example, a component that is configured as a wear partner for use on rolled material or for guiding the rolled material. The term component as used in this application includes, for example but not exclusively, sliding guides in roller tables, guide rulers, rolls or cylinders, for example also support rollers, that interact with other cylinders.

Preferably, the at least one functional layer consists of a relatively harder and/or more wear-resistant material than the sacrificial layer.

According to a further aspect, as a component within the meaning of the application, a roll for use on hot rolled material in a hot rolling mill is provided, which has a roll body comprising a roll shell of a base material and at least one functional layer of at least one material different from the base material, wherein the material of the at least one functional layer has greater wear resistance than the base material, wherein the roll body comprises at least one further, outer layer as a sacrificial layer, which at least partially encloses the at least one functional layer, and the sacrificial layer consists of a material which has a lower wear resistance than the at least one functional layer.

As used in this application, a roll for use on hot rolled material is a roll or cylinder as a roller table roll, cylinder of a rolling mill, cylinder of a continuous casting machine or continuous casting guide or of another unit intended to support, handle and/or transport hot rolled material.

The roll body and/or the roll shell are, for example, substantially cylindrical, wherein the shell surface of the roll can also be conical or cambered. The shell body of the roll may have a plurality of layers that may form a composite with corresponding material properties. At least one outer layer of the roll shell is configured as what is referred to as a functional layer, which means that the material of the functional layer has the desired properties for use on the rolled material with regard to wear resistance, temperature resistance, hardness or ductility.

As used in this application, a functional layer is understood to be a wear-protection layer which consists of a material which is more wear-resistant than the base material of the roll body and/or than other layers of the roll.

Preferably, the sacrificial layer does not meet all the requirements for use on the rolled material; in particular, this sacrificial layer exhibits lower wear resistance. With regard to surface finish (roughness, waviness and dimensional stability), the sacrificial layer may nevertheless have the desired application-specific properties.

In principle, provision can be made for the roll shell to comprise one or more supplementary layers arranged beneath at least one functional layer. Supplementary layers can perform various functions, e.g. separating two hard and brittle layers to prevent cracking or separating two different hard layers to prevent mixing, but can also function as a sacrificial layer.

The supplementary layers may, for example, have lower resistance and greater ductility than the other layers and thus allow the reduction of stresses and the prevention of cracks in the boundary area to a functional layer of high hardness and wear resistance.

The term sacrificial layer means that this partial layer does not have the properties required by the application, e.g. in a rolling mill, but that a partial layer or part of the entire layer is deliberately applied in order to provide the underlying layer area with particularly advantageous properties or to generally promote its effective, optimal use for the application.

The sacrificial layer may, for example, be applied above a hard layer and form the outermost shell surface of the roll. This may be machined to provide a desired surface quality, for example a certain surface roughness.

The sacrificial layer may completely or partially enclose an outer functional layer. If the roll has, above a hard layer, an additional soft layer that has been mechanically reworked, this has various advantages. It makes it easier to achieve a good surface quality during coating. Furthermore, mechanical processing of the sacrificial layer is considerably easier. The sacrificial layer may be reworked using an easier and less expensive method, such as turning or re-turning to a nominal diameter. Finally, the tool used for this is less expensive and easier to handle. The valuable hard layer or functional layer is completely or almost completely preserved, since the application and removal of the softer layer can be optimally tailored to the application. The thickness of the softer layer may be freely selected within wide limits and thus adapted to the requirements of the overall system. Preserving the functional layer is one aspect of the invention, in particular when the functional layer has a property gradient in which the best properties are achieved directly at the surface.

This also increases the freedom of configuration when applying the hard layer, in preferred embodiments a layer that has a structural and property gradient, or several layers that have a structural and property gradient from layer to layer, or several layers that have a structural and property gradient from layer to layer and within the layers. If, for example, 200 to 500 micrometres of material had to be removed after coating, complex optimization of alloy composition and process parameters with the aim of achieving optimal properties near the edge, e.g. in the form of high resistance or good corrosion resistance, would often be pointless. Sophisticated modern coating concepts in which, for example, the proportion of hard foreign phases such as tungsten carbide or titanium carbide increases continuously (in one layer) or discontinuously (from layer to layer) or both continuously and discontinuously, could not be applied or could only be applied to a limited extent in this case.

The disadvantages of the prior art are overcome by applying a preferably softer sacrificial layer or covering layer, which is partially or almost completely removed during mechanical processing. Any residues of the soft layer are quickly removed during industrial use due to their low wear resistance and do not impair the functionality of the layer. The hard layer can then be used exactly in line with its original purpose because it is completely preserved. The property profile, which correlates with the macroscopic and microscopic structure of the layer, can thus be adjusted according to specifications or as desired. Any thickness variation over length and width or in the axial and tangential directions that may be due to the lack of processing of this hard layer will be evened out over the course of operation due to the mechanical load that occurs.

An optimal combination of applying and subsequently partially removing the entire layer is responsible for ensuring that, on the one hand, the technical properties are particularly advantageous and, on the other hand, the economic efficiency of the product is maximized.

Provision is preferably made for the at least one functional layer to consist of a relatively harder and/or more wear-resistant material than the sacrificial layer.

In a rotationally symmetrical component such as a roll, for example, the functional layer may exhibit a radially running structural and/or property gradient. For example, the functional layer may exhibit a hardness gradient from the inside to the outside, for example from softer to harder.

The functional layer may, for example, comprise a steel containing a specific proportion of hard foreign phases such as tungsten carbide or titanium carbide. These foreign phases may be distributed in a layer, i.e. continuously, so that a hardness gradient is achieved. Such a hardness gradient is readily achieved when a hard functional layer within the meaning of the present application forms the shell surface of the component or, for example, the roll shell of the roll with a softer covering layer as a sacrificial layer. The sacrificial layer allows the set gradient to be maintained.

Almost all common steel grades may be considered as the material for the main body of the component, for example structural steels such as S355J or heat-treatable steels such as 25CrMo4.

A wear-resistant hot-work steel such as 1.2344 or a high-speed steel such as 1.3344 may be considered as the material for the at least one functional layer. Martensitic stainless steels, for example, based on 1.4057, nickel-based alloys such as Inconel 625 and Inconel 718, or cobalt-based alloys such as Stellite 6 and Stellite 21 are also suitable. Particularly wear-resistant layers also contain hard phases such as tungsten carbides and/or titanium carbides. In extreme cases, the volume fraction of the hard phases may exceed that of the matrix.

In a preferred configuration of the component or roll, a plurality of functional layers is provided which have different properties and/or consist of different materials.

The plurality of functional layers may, for example, form a radial structural and/or property gradient of the roll shell.

In a preferred variant of the component, provision may be made for its shell surface to be configured as a single-surface shell surface, i.e. for it to have no steps or diameter jumps. As already mentioned above, the shell surface of a roll as the component may be cylindrical, conical, cambered or S-shaped.

A further aspect of the disclosure relates to a method for producing or restoring a mechanically, in particular tribologically, stressed component according to one of claims 1 to 8, the component comprising a main body of a base material and at least one functional layer applied to the main body and consisting of at least one material different from the base material, comprising the following method steps:
Providing a main body of a base material,
Applying at least one wear-resistant functional layer to the main body,
Applying an outer sacrificial layer to the functional layer, wherein the sacrificial layer consists of a material which has material properties differing from the material properties of the functional layer and which has a lower wear resistance than the at least one functional layer,
Reworking the main body with the removal of material to produce a shell surface with predefined dimensions which is closed at least in the area of a functional surface.

The method steps are preferably carried out in the order in which they are listed.

The application of the at least one functional layer and/or of the sacrificial layer is preferably selected from a group of methods including build-up welding, thermal spraying, plasma coating, casting, centrifugal casting, vapour deposition, dusting, galvanic coating and chemical coating.

The reworking may be carried out, for example, by turning and/or milling and/or grinding.

The thickness of the at least one functional layer and/or of the sacrificial layer may be selected so that the sacrificial layer at least partially encloses the at least one functional layer after the removal of material.

For example, the shell surface may be produced as a single-surface shell surface.

In one variant of the method, a plurality of functional layers may be applied, the functional layers having different properties and/or consisting of different materials, such that the plurality of functional layers form a structural and/or property gradient.

A further aspect of the disclosure relates to a method for producing or restoring a roll for use on hot rolled material in a hot rolling mill, in particular for producing or restoring a roll which has a roll body comprising a roll shell of a base material and at least one functional layer of at least one material different from the base material, comprising the following processing steps:
Providing a roll body with a roll shell of a base material,
Applying at least one wear-resistant functional layer to the roll body,
Applying an outer sacrificial layer to the functional layer, wherein the sacrificial layer consists of a material which has material properties differing from the material properties of the functional layer and which has a lower wear resistance than the at least one functional layer,
Reworking the roll shell with the reduction of the diameter to obtain a closed roll shell surface with a predefined external diameter.

The method steps are preferably carried out in the order in which they are listed.

The application of the at least one functional layer and/or of the sacrificial layer may be carried out, for example, by build-up welding, thermal spraying, casting, vapour deposition, plasma coating, centrifugal casting, dusting, galvanic coating or chemical coating.

The method for producing or restoring a mechanically stressed component may further comprise utilizing the heat supplied during application of the sacrificial layer to influence the ductility of the underlying functional layer. The functional layer is subjected to a tempering process by the sacrificial layer.

Reworking may be carried out by turning and/or milling and/or grinding.

The thickness of the at least one functional layer and/or of the sacrificial layer is preferably selected so that the sacrificial layer at least partially encloses the at least one functional layer after the diameter has been reduced.

The roll shell surface is preferably produced as a single-surface shell surface. It may, for example, be entirely closed.

In the method, provision may be made for a plurality of functional layers to be applied which have different properties and/or consist of different materials, such that the plurality of functional layers form a preferably radial structural and/or property gradient of the roll shell. The described layers with the corresponding properties may be matched to different loads acting on the roll shell at different times such that the best possible roll shell properties exist with regard to the respective outer loads, corresponding to the arrangement of the layers on the roll.

The wear and/or load resistance of the roll may, for example, be optimized in an application-oriented manner, wherein a method for application-oriented optimization may include the acquisition of tribological data during the production and/or restoration of at least one roll, the acquisition of wear and/or load data resulting from the operational use of the roll, the correlation of the tribological data from the production and/or restoration of the roll with the wear and/or load data from the operation of an electronic database and the automatic load-oriented configuration and/or modification of the structure of the roll shell and/or the automatic modification of the operational load of the roll.

The optimization of wear and/or load resistance of the component or the roll may, for example, also be carried out using data regarding the removal of material during operation and/or during restoration of the component.

The tribological data are preferably measured data selected from a group of measured data comprising torques, cutting forces, feed forces, frictional forces, friction coefficients and temperatures during machining of the component or the roll shell and surface roughness of the roll shell surface immediately after machining of the roll shell.

The tribological data relating to the geometry of a roll may be acquired in both location-related and time-related terms.

The wear and/or load data resulting from the operation of the roll are preferably measured data, which are either temporarily recorded on the roll in operation or acquired during operation online.

The wear data may include measured surface properties selected from a group of measured data on roughness, waviness, profile, surface hardness, friction coefficient of the shell surface of the roll and the structure of the wear marks in the shell surface of the roll.

Machining methods with geometrically defined and undefined edges can also be considered to be tribometers. Therefore, the recording of the removal of material and the associated resulting parameters such as surface quality and the shape and position of the surfaces may be taken into account for optimizing the wear and/or load resistance of the component.

The load data may be selected from a group of data comprising the point loads acting on the roll, line loads, surface pressures, rotational speeds and the slipping of the roll as well as the temperature and/or nature of the rolled material and/or the media used for cooling rolled goods.

The method may include automatic evaluation of the corrected data with the aid of at least one expert system and/or using methods based on machine learning methods, in particular based on artificial neural networks, deep artificial neural networks, decision trees, ensemble methods based on decision trees, linear or non-linear regression models with or without regularization, support vector machines with linear, polynomial or other kernel functions, or the like.

The invention is explained below using an exemplary embodiment shown in the drawings.

### BRIEF DESCRIPTION OF THE DRAWINGS

FIG. 1 shows a schematic representation of a partial section through a roll configured according to the prior art.

FIG. 2 shows a schematic representation of several production stages of the roll shown in FIG. 1.

FIG. 3 shows a schematic representation of the method for producing or restoring a roll according to the disclosure using several partial sectional views.

FIG. 4 shows a partial section through a roll after a certain operating time.

FIG. 5 shows a schematic representation of a multi-layer system of a roll.

### DETAILED DESCRIPTION

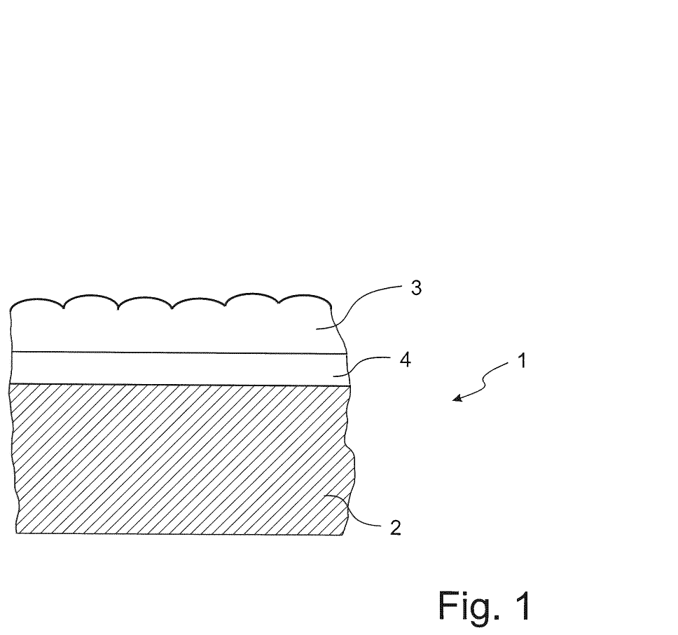

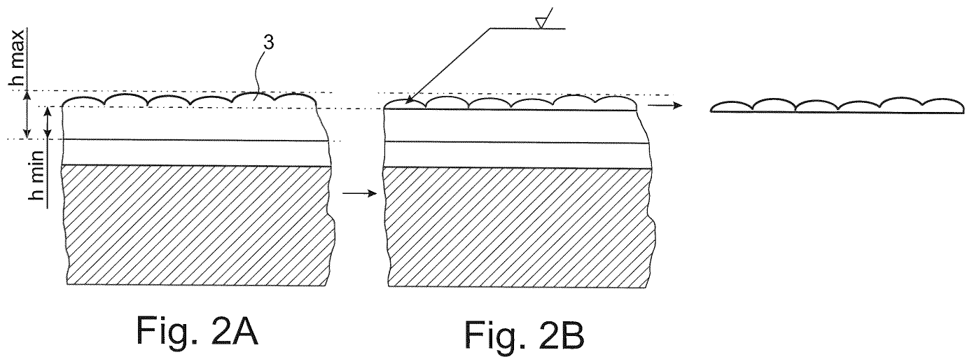

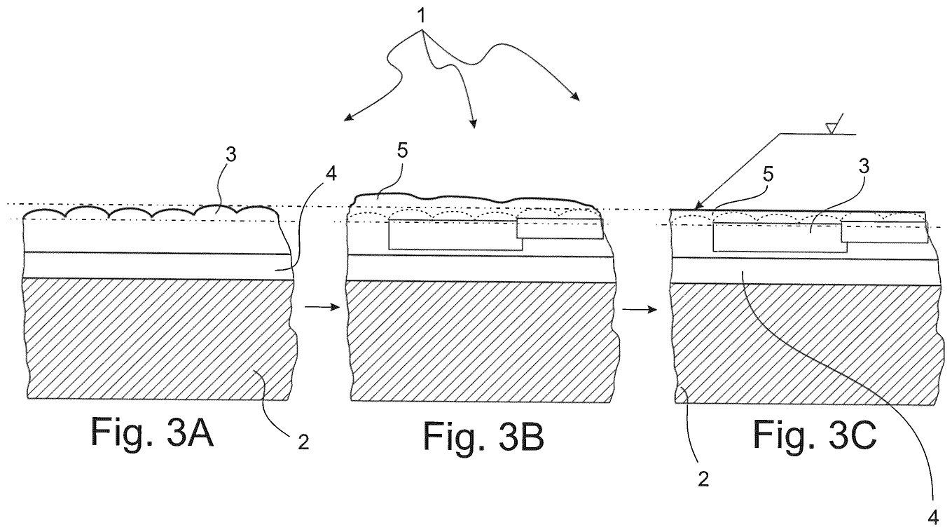

Reference is first made to FIGS. 1 and 2, which show several partial sectional views of a prior art roll in various stages of production. The same reference numerals used in relation to FIGS. 1 and 2 are used for the roll shown in FIGS. 3 to 5.

The roll 1 shown in FIGS. 1 and 2 is shown in each case as a partial sectional view, the sectional view being shown above an axis of symmetry of the roll 1. The roll 1 comprises a roll body 2 of steel as the base material and a shell layer comprising what is referred to as a functional layer 3. A supplementary layer 4 may be arranged below the functional layer 3.

Either during new production or during restoration of the roll 1, the functional layer is usually applied as a wear protection layer with appropriate material properties, for example by build-up welding, to the supplementary layer 4 or directly to the roll body 2. In order to ensure that the shell surface of the roll has the appropriate surface quality, i.e. surface roughness or surface flatness according to the specifications, it is machined after application of the functional layer 3, i.e. usually turned to the nominal diameter of the roll 1 and ground accordingly. The condition of the roll 1 after application of the functional layer 3 is shown in FIG. 2A, and the condition after machining of the surface is illustrated in FIG. 2B. It can clearly be seen that reworking the surface of the functional layer 3 involves a corresponding amount of effort.

The method for producing or restoring a mechanically stressed component and the component (a roll 1 in the example described) are illustrated in FIGS. 3 to 5. As already mentioned at the beginning, suitable components include, for example, but not exclusively, sliding guides in roller tables, guide rulers, rolls or cylinders, for example also support rollers, that interact with other cylinders or other mechanically loaded components subject to wear.

FIG. 3A shows the condition of the roll 1 after application of the functional layer 3 of a wear-resistant and hard and/or tough material, which has more favourable wear properties than the base material of the roll body 2 and/or a supplementary layer 4 arranged therebetween. The supplementary layer 4 may, for example, consist of a relatively soft material based on the austenitic stainless steel 1.4404. The functional layer 3, which was applied by build-up welding in the exemplary embodiment described, consists, for example, of a wear-resistant hot-work steel such as 1.2344 or a high-speed steel such as 1.3344 comprising foreign phases of tungsten carbide and/or titanium carbide, which achieve a corresponding wear resistance of the functional layer 3.

Immediately after its application to the roll body 2 according to FIG. 3A, the functional layer 3 certainly does not meet the requirements in terms of the surface quality of the finished component. In a next step, which is illustrated in FIG. 3B, a sacrificial layer 5 is applied to the functional layer 3, which consists, for example, of the same material as the other supplementary layers or of a different material, since the sacrificial layer may, for example, have lower ductility than the supplementary layers further inside (e.g. buffer layers) or, for example, unlike these, does not have to meet any special requirements with regard to thermal conduction and/or thermal expansion. The sacrificial layer 5 does not meet the application-specific requirements in terms of wear resistance and/or hardness and/or toughness of the material.

After applying the sacrificial layer 5, the roll shell has an excess dimension, which is reduced to the nominal diameter of the roll 1 in a further method step by appropriate reworking such as milling, grinding or turning and, as illustrated in FIG. 3C, ultimately has the desired surface roughness according to the specifications based on the application of the roll 1.

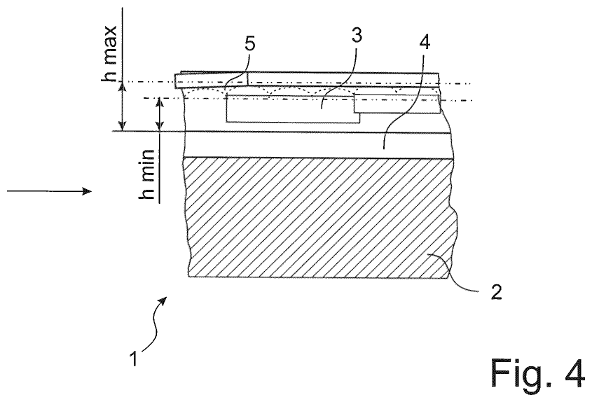

FIG. 4 shows a partial section through the roll 1 after a certain service life or operating time. Parts of the sacrificial layer have been removed as a result of stress, but parts of it are still present. Parts of the functional layer 3 are also worn away, with the removal in both layers generally varying in intensity. The thickness of the functional layer 3 becomes more uniform over time.

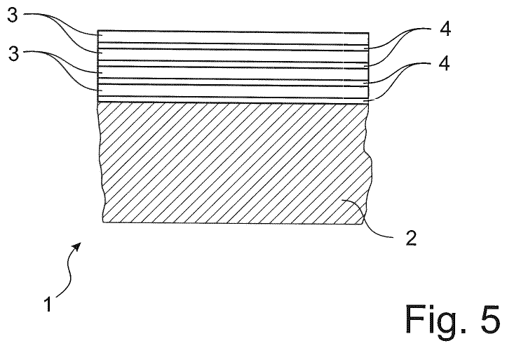

FIG. 5 illustrates a multi-layer system of the shell of the roll comprising a plurality of functional layers 3 and a plurality of supplementary layers 4 arranged to achieve a radial hardness gradient. A sacrificial layer 5, not shown in FIG. 5, is applied above the layer arrangement of functional layers 3. This sacrificial layer 5 is reworked, as in the example according to FIG. 3, with regard to the surface roughness and the nominal diameter of the roll, through appropriate reworking.

### LIST OF REFERENCE NUMERALS

1 Roll
2 Roll body
3 Functional layer
4 Supplementary layer
5 Sacrificial layer

1.-14. (canceled)

15. A component in a rolling mill, the component being subject to mechanically stress, the component comprising:
a main body of a base material; and
at least one functional layer (3) applied to the main body and consisting of at least one material different from the base material,
wherein the material of the at least one functional layer (3) has a greater wear resistance than the base material,
wherein the main body comprises at least one further, outer layer as a sacrificial layer (5),
wherein the sacrificial layer (5) at least partially encloses the at least one functional layer (3), and
wherein the sacrificial layer (5) consists of a material which has a lower wear resistance than the at least one functional layer (3).

16. The component according to claim 15,
wherein the component is tribologically stressed.

17. The component according to claim 16,
wherein the at least one functional layer (3) consists of a harder and/or more wear-resistant material than the sacrificial layer (5).

18. The component according to claim 16,
wherein the component is a roll (1) for a hot rolling mill.

19. The component according to claim 18,
wherein the functional layer (3) has a radially running structural and/or property gradient.

20. The component according to claim 16,
wherein the at least one functional layer (3) includes a plurality of functional layers (3) having different properties and/or consisting of different materials.

21. The component according to claim 20,
wherein the plurality of functional layers (3) form a radial structural and/or property gradient of a roll shell.

22. The component according to claim 21,
wherein the roll shell has a single-surface shell surface.

23. A method for producing or restoring a tribologically stressed component of a rolling mill, comprising:
providing a main body of a base material;
applying at least one wear-resistant functional layer to the main body; and
applying an outer sacrificial layer (5) to the at least one wear-resistant functional layer (3),
wherein the outer sacrificial layer (5) consists of a material having material properties differing from material properties of the wear-resistant functional layer (3) and having a lower wear resistance than the at least one wear-resistant functional layer (3); and
reworking the main body by removing material to produce a shell surface with predefined dimensions which is closed at least in an area of a functional surface.

24. The method according to claim 23,
wherein the tribologically stressed component is a roll (1), and
wherein reworking the main body includes reworking a shell of the roll by reducing a diameter thereof to obtain a closed roll shell surface with a predefined external diameter.

25. The method according to claim 23,
wherein the applying the at least one wear-resistant functional layer (3) and/or applying the outer sacrificial layer (5) includes one or more of build-up welding, thermal spraying, plasma coating, casting, centrifugal casting, vapor deposition, dusting, galvanic coating, and chemical coating.

26. The method according to claim 23,
wherein the reworking is carried out by turning and/or milling and/or grinding.

27. The method according to claim 23,
wherein a thickness of the at least one wear-resistant functional layer (3) and/or of the outer sacrificial layer (5) is selected so that the outer sacrificial layer (5) at least partially encloses the at least one wear-resistant functional layer after removing the material.

28. The method according to claim 24,
wherein the shell surface is produced as a single-surface shell surface.

29. The method according to claim 23,
wherein applying the at least one wear-resistant functional layer includes applying a plurality of functional layers, the functional layers having different properties and/or consisting of different materials, such that the plurality of functional layers (3) form a radial structural and/or property gradient.
